(19) United States
(12) Patent Application Publication
(10) Pub. No.: US 2023/0104233 A1
(43) Pub. Date: Apr. 6, 2023

(54) Method for Preparing LED Display Module

(71) Applicant: LEYARD OPTOELECTRONIC CO., LTD., Beijing (CN)

(72) Inventors: Wei ZHENG, Beijing (CN); Mengqiang WANG, Beijing (CN); Li MA, Beijing (CN)

(21) Appl. No.: 17/890,284

(22) Filed: Aug. 18, 2022

(30) Foreign Application Priority Data
Sep. 17, 2021 (CN) 202111094226.9

(51) Int. Cl. H01L 33/00; H01L 25/075

(52) U.S. Cl. CPC H01L 33/005; H01L 25/0753

(57) ABSTRACT

The present disclosure provides a method for preparing an LED display module, including following steps: step S10: machining a first enclosure around a front surface of a lamp panel; step S30: filling the accommodating pool with glue, and performing a vacuum defoaming treatment on the lamp panel filled with the glue; step S40: performing a first curing treatment on the defoamed lamp panel; step S50: placing the lamp panel with the first enclosure removed in an accommodating appliance, enabling the front surface of the lamp panel with the first enclosure removed to face the bottom of the accommodating appliance, and immersing lamp beads on the lamp panel with the first enclosure removed into defoaming glue in the accommodating appliance; and step S60: applying an acting force, which faces the bottom of the accommodating appliance, to a back surface of the lamp panel with the first enclosure removed.

### CROSS-REFERENCE TO RELATED APPLICATION

The present disclosure claims the priority to Chinese Patent Application No. 202111094226.9, filed to the Chinese Patent Office on Sep. 17, 2021 and entitled “Method for Preparing LED Display Module”, which is incorporated in its entirety herein by reference.

### TECHNICAL FIELD

The present disclosure relates to a technical field of LED display, and in particular to a method for preparing an LED display module.

### BACKGROUND

With the development of LED display technology, the disclosure of LED display screens is more and more extensive, the pixel pitches of LEDs are getting smaller and smaller, the sizes of LED devices used are also getting smaller and smaller, and the anti-collision, anti-corrosion, moisture-proof and anti-static ability of LED modules are correspondingly required to be stronger and stronger.

In a packaging method of an LED module provided in related art, a circuit board provided with LED lamp beads, a solid light-transmitting glue layer and a light-transmitting film are stacked in sequence, wherein one surface of the circuit board provided with the LED lamp beads faces the light-transmitting film, and a pressure is applied to the circuit board, the light-transmitting glue layer and the light-transmitting film, which are stacked together, in a preset temperature environment, so as to obtain the LED module.

However, in the above-mentioned packaging process, the air existing in lamp slits of the lamp beads cannot be fully exhausted, and the refractive indexes of the light-transmitting glue layer and the light-transmitting film are different from that of the air, resulting in an uneven surface luminescence phenomenon on an LED display surface, which affects the display effect.

### SUMMARY

The main purpose of the present disclosure is to provide a method for preparing an LED display module, so as to solve a problem in related art that air existing in lamp slits of lamp beads cannot be exhausted, thus affecting a display effect.

In order to achieve the above purpose, the present disclosure provides a method for preparing an LED display module, including following steps: step S10: machining a first enclosure around a front surface of a lamp panel, so as to form an accommodating pool on the front surface of the lamp panel; step S30: filling the accommodating pool with glue, and performing a vacuum defoaming treatment on the lamp panel filled with the glue, so as to obtain a defoamed lamp panel; step S40: performing a first curing treatment on the defoamed lamp panel, so as to obtain a lamp panel that has been subjected to the first curing treatment; step S50: removing the first enclosure, and placing the lamp panel with the first enclosure removed in an accommodating appliance, enabling the front surface of the lamp panel with the first enclosure removed to face a bottom of the accommodating appliance, and immersing lamp beads on the lamp panel with the first enclosure removed into defoaming glue in the accommodating appliance, wherein the bottom of the accommodating appliance is a plane portion; step S60: applying an acting force, which faces the bottom of the accommodating appliance, to a back surface of the lamp panel with the first enclosure removed, and immersing the front surface of the lamp panel into the defoaming glue to obtain an immersed lamp panel; and step S70: performing a second curing treatment on the immersed lamp panel, so as to obtain a lamp panel that has been subjected to the second curing treatment, and then an LED display module is obtained.

In some embodiments, between the step S10 and the step S30, the method for preparing the LED display module further includes: step S20: machining a second enclosure around the back surface of the lamp panel.

In some embodiments, the step S30 includes: step S31: filling the accommodating pool with the glue, and performing the vacuum defoaming treatment in a vacuum box on the lamp panel filled with the glue; and step S32: performing the vacuum defoaming treatment for 3 minutes to 10 minutes, so as to obtain the defoamed lamp panel.

In some embodiments, the step S40 includes: step S41: placing the defoamed lamp panel in a curing chamber to perform the first curing treatment, wherein a temperature in the curing chamber is between 20° C. and 40° C.; and step S42: performing the first curing treatment for 1 hour to 4 hours, so as to obtain the lamp panel that has been subjected to the first curing treatment.

In some embodiments, in the step S42: a viscosity of the glue on the lamp panel that has been subjected to the first curing treatment is between 2000 mPa·s and 10000 mPa·s.

In some embodiments, the step S50 includes: step S51: fabricating, by using a flexible film, the accommodating appliance capable of accommodating the lamp panel that has been subjected to the first curing treatment; step S52: filling the accommodating appliance with the defoaming glue, so that the accommodating appliance contains the defoaming glue; and step S53: removing the first enclosure, and placing the lamp panel with the first enclosure removed in the accommodating appliance, enabling the front surface of the lamp panel with the first enclosure removed to face the bottom of the accommodating appliance, and immersing the lamp beads on the lamp panel with the first enclosure removed into the defoaming glue.

In some embodiments, in the step S51, the accommodating appliance is placed on a flat plate, so that the bottom of the accommodating appliance forms the plane portion.

In some embodiments, the step S60 includes: step S61: placing a fixture on the back surface of the lamp panel with the first enclosure removed; and step S62: placing a counterweight block above the fixture, so that the fixture applies the acting force, which faces the bottom of the accommodating appliance, to the back surface of the lamp panel with the first enclosure removed, and then the immersed lamp panel is obtained.

In some embodiments, in the step S62, the counterweight block is placed above the fixture, and the counterweight block is fixed on the fixture with an adhesive tape, so that the fixture applies the acting force, which faces the bottom of the accommodating appliance, to the back surface of the lamp panel with the first enclosure removed.

In some embodiments, the step S70 includes: step S71: placing the immersed lamp panel in the curing chamber to perform the second curing treatment, wherein a temperature in the curing chamber is between 20° C. and 1000° C.; step S72: performing the second curing treatment for 2 hours to 24 hours, so as to obtain the lamp panel that has been subjected to the second curing treatment; and step S73: removing the accommodating appliance, the flat plate and an excess colloid around the lamp panel that has been subjected to the second curing treatment, so as to obtain the LED display module.

In some embodiments, in the step S30, upper surfaces of the lamp beads are immersed into the glue.

In some embodiments, a plurality of electronic devices are arranged on the back surface of the lamp panel, the fixture includes a supporting plate and a plurality of supporting legs that are arranged on a lower surface of the supporting plate at intervals, and the plurality of supporting legs avoid the plurality of electronic devices.

By applying the technical solution of the present disclosure, the method for preparing an LED display module includes the following steps: step S10: machining a first enclosure around a front surface of a lamp panel, so as to form an accommodating pool on the front surface of the lamp panel; step S30: filling the accommodating pool with glue, and performing a vacuum defoaming treatment on the lamp panel filled with the glue, so as to obtain a defoamed lamp panel; step S40: performing a first curing treatment on the defoamed lamp panel, so as to obtain a lamp panel that has been subjected to the first curing treatment; step S50: removing the first enclosure, and placing the lamp panel with the first enclosure removed in an accommodating appliance, enabling the front surface of the lamp panel with the first enclosure removed to face a bottom of the accommodating appliance, and immersing lamp beads on the lamp panel with the first enclosure removed into defoaming glue in the accommodating appliance, at this time, a colloid on the lamp panel with the first enclosure removed is fused with the defoaming glue in the accommodating appliance. Since the two are made of the same material, bubbles are unlikely to be generated at an intersection therebetween, thereby ensuring that no bubble is generated inside a colloid obtained after the second curing treatment, wherein the bottom of the accommodating appliance is a plane portion; step S60: applying an acting force, which faces the bottom of the accommodating appliance, to a back surface of the lamp panel with the first enclosure removed, and immersing the front surface of the lamp panel into the defoaming glue to obtain an immersed lamp panel; and step S70: performing a second curing treatment on the immersed lamp panel, so as to obtain a lamp panel that has been subjected to the second curing treatment, and then an LED display module is obtained. After the step S30, the defoamed lamp panel is obtained, residual air in the front surface of the LED display module is removed, and a probability that surfaces of the lamp beads contact a surface of the colloid to generate bubbles is reduced. Furthermore, glue that has been defoamed is used twice to ensure that no bubble is generated inside the colloid, and at the same time, a probability of generating residual bubbles due to the contact of different objects is greatly reduced, which is conducive to exhausting the air existing in lamp slits of the lamp beads, and improving the display effect of the LED display module. Therefore, the technical solution of the present disclosure effectively solves the problem in related art that the air existing in the lamp slits of the lamp beads cannot be exhausted, thus affecting the display effect. In addition, the bottom of the accommodating appliance is a plane portion, which ensures flatness of the surface of the lamp panel facing the bottom of the accommodating appliance after the first enclosure is removed, and there is no uneven phenomenon.

### BRIEF DESCRIPTION OF THE DRAWINGS

The drawings forming a part of the present disclosure are used for providing a further understanding of the present disclosure, and exemplary embodiments of the present disclosure and descriptions thereof are used for explaining the present disclosure, but do not constitute improper limitations of the present disclosure. In the drawings:

FIG. 1 shows a flow diagram of an embodiment of a method for preparing an LED display module according to the present disclosure;

FIG. 2 shows a schematic structural diagram when a front surface of a lamp panel is facing upward in the case where the method for preparing the LED display module shown in FIG. 1 is applied; and

FIG. 3 shows a schematic structural diagram when the front surface of the lamp panel faces a bottom of an accommodating appliance in the case where the method for preparing the LED display module shown in FIG. 1 is applied.

The above drawings include the following reference signs:

1, lamp bead; 2, panel body; 10, first enclosure; 20, second enclosure; 31, accommodating appliance; 32, flat plate; 33, fixture; 34, counterweight block.

### DETAILED DESCRIPTION OF THE EMBODIMENTS

A clear and complete description of technical solutions in the embodiments of the present disclosure will be given below, in combination with the drawings in the embodiments of the present disclosure. Apparently, the embodiments described below are merely a part, but not all, of the embodiments of the present disclosure. The following description of at least one exemplary embodiment is merely illustrative and is in no way used as any limitation to the present disclosure and its disclosure or use. All of other embodiments, obtained by those of ordinary skill in the art based on the embodiments of the present disclosure without any creative effort, fall into the protection scope of the present disclosure.

It should be noted that, terms used herein are for the purpose of describing specific embodiments, and are not intended to limit the exemplary embodiments according to the present disclosure. As used herein, unless the context clearly dictates otherwise, a singular form is intended to include a plural form as well. In addition, it should also be understood that, when the terms “comprising” and/or “including” are used in this specification, they indicate that the presence of features, steps, operations, devices, components and/or combinations thereof.

Unless specifically stated otherwise, relative arrangements, numerical expressions and numerical values of components and steps set forth in these embodiments do not limit the scope of the present disclosure. Meanwhile, it should be understood that, for the convenience of description, the dimensions of various portions shown in the drawings are not drawn according to an actual proportional relationship. Techniques, methods and devices known to those of ordinary skill in related art may not be discussed in detail, but where appropriate, such techniques, methods and devices should be considered part of the authorized specification. In all examples shown and discussed herein, any specific value should be construed as illustrative only and not as restrictive. Accordingly, other examples of the exemplary embodiments may have different values. It should be noted that similar reference signs and letters refer to similar items in the following figures, so once a certain item is defined in one figure, it does not require further discussion in subsequent figures.

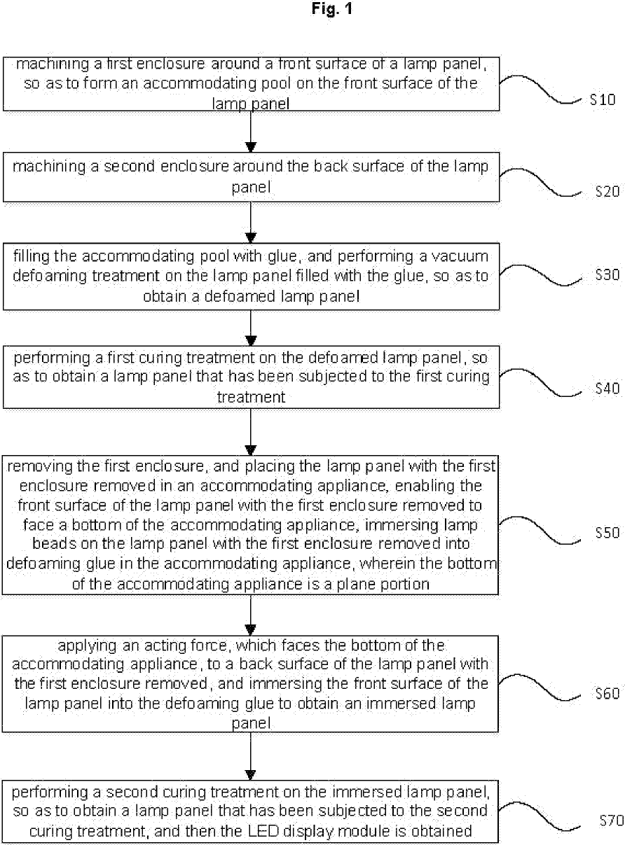

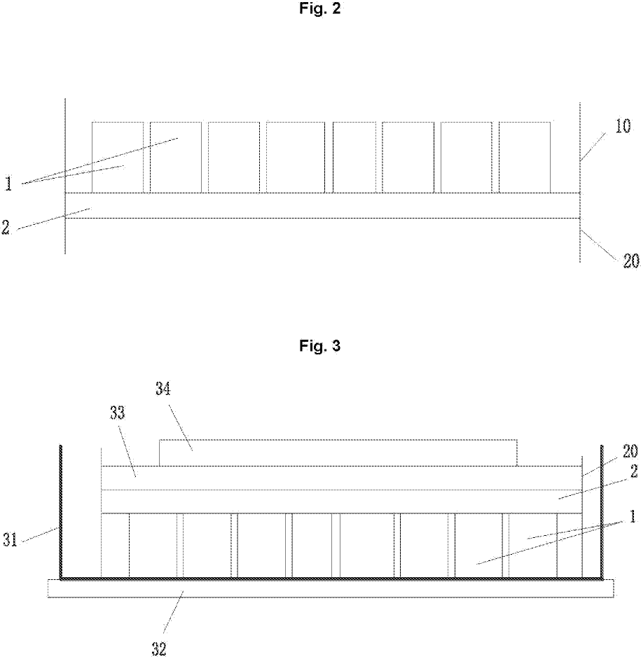

As shown in FIG. 1 to FIG. 3, a method for preparing an LED display module in the present embodiment includes following steps: step S10: machining a first enclosure 10 around a front surface of a lamp panel, so as to form an accommodating pool on the front surface of the lamp panel; step S30: filling the accommodating pool with glue, and performing a vacuum defoaming treatment on the lamp panel filled with the glue, so as to obtain a defoamed lamp panel, wherein the first enclosure 10 blocks the glue so as to prevent the glue from overflowing from the accommodating pool; step S40: performing a first curing treatment on the defoamed lamp panel, so as to obtain a lamp panel that has been subjected to the first curing treatment; on order to prevent interference between the first enclosure 10 and an accommodating appliance 31, step S50: removing the first enclosure 10, and placing the lamp panel with the first enclosure removed in the accommodating appliance 31, enabling the front surface of the lamp panel with the first enclosure removed to face a bottom of the accommodating appliance 31, and immersing lamp beads 1 on the lamp panel with the first enclosure removed into defoaming glue in the accommodating appliance, wherein the bottom of the accommodating appliance 31 is a plane portion; step S60: applying an acting force, which faces the bottom of the accommodating appliance 31, to a back surface of the lamp panel with the first enclosure removed, and immersing the front surface of the lamp panel into the defoaming glue to obtain an immersed lamp panel, wherein since the acting force, which faces the bottom of the accommodating appliance 31, is applied to the back surface of the lamp panel with the first enclosure removed, a colloid on the front surface of the lamp panel with the first enclosure removed is more compact; and step S70: performing a second curing treatment on the immersed lamp panel, so as to obtain a lamp panel that has been subjected to the second curing treatment, and then an LED display module is obtained.

By applying the technical solution of the present disclosure, step S50: removing the first enclosure 10, and placing the lamp panel with the first enclosure removed in the accommodating appliance 31, enabling the front surface of the lamp panel with the first enclosure removed to face the bottom of the accommodating appliance 31, and immersing lamp beads 1 on the lamp panel with the first enclosure removed into defoaming glue in the accommodating appliance 31, at this time, a colloid on the lamp panel with the first enclosure removed is fused with the defoaming glue in the accommodating appliance 31, since the two are made of the same material, bubbles are unlikely to be generated at an intersection therebetween, thereby ensuring that no bubble is generated inside a colloid obtained after the second curing treatment, wherein the bottom of the accommodating appliance 31 is a plane portion; step S60: applying an acting force, which faces the bottom of the accommodating appliance 31, to a back surface of the lamp panel with the first enclosure removed, and immersing the front surface (the front surface of the lamp panel herein specifically refers to a front surface of s panel body 2) of the lamp panel into the defoaming glue to obtain an immersed lamp panel; and step S70: performing a second curing treatment on the immersed lamp panel, so as to obtain a lamp panel that has been subjected to the second curing treatment, and then an LED display module is obtained. After the step S30, the defoamed lamp panel is obtained, residual air in the front surface of the LED display module is removed, and a probability that surfaces of the lamp beads 1 contact a surface of the colloid to generate bubbles is reduced. Furthermore, glue that has been defoamed is used twice to ensure that no bubble is generated inside the colloid, and at the same time, a probability of generating residual bubbles due to the contact of different objects is greatly reduced, which is conducive to exhausting the air existing in lamp slits of the lamp beads 1, and improving the display effect of the LED display module. Therefore, the technical solution of the present embodiment effectively solves the problem in related art that the air existing in the lamp slits of the lamp beads cannot be exhausted, thus affecting the display effect. In addition, the bottom of the accommodating appliance 31 is a plane portion, which ensures flatness of the surface of the lamp panel facing the bottom of the accommodating appliance 31 after the first enclosure is removed, and there is no uneven phenomenon. The lamp panel of the present embodiment includes the panel body 2 and a plurality of lamp beads 1 arranged on the front surface of the panel body. A back surface of the panel body 2 is provided with a plurality of electronic devices.

It should be noted that: the “the front surface of the lamp panel” and “the front surface of the panel body 2” mentioned above refer to surfaces on which the lamp beads are provided. Correspondingly, “the back surface of the lamp panel” and “the back surface of the panel body 2” refer to surfaces on which the lamp beads 1 are not provided.

In the present embodiment, the front surface of the lamp panel with the first enclosure removed is placed downward in the accommodating appliance 31, and the acting force, which faces the bottom of the accommodating appliance, is applied to the lamp panel with the first enclosure removed, so that a smoothness of a front surface of the obtained LED display panel is guaranteed. During a process of directly placing the lamp panel in the accommodating appliance 31, bubbles are easily generated on a contact surface between the defoaming glue and the lamp beads 1, and the lamp panel is inversed placed in the accommodating appliance 31, such that bubbles between adjacent lamp beads 1 are difficult to be discharged. Therefore, filling the glue into the accommodating pool and the first curing treatment are performed at first, so that the lamp beads 1 are entirely wrapped in the colloid without bubbles therein, that is, there is no bubble between the adjacent lamp beads, and then the light panel is put into the accommodating appliance 31. Such an arrangement not only ensures the flatness of the front surface of the LED display module, but also ensures that no bubble exists between adjacent lamp beads 1.

When the lamp panel with the first enclosure removed is put into the accommodating appliance 31, one end of the lamp panel with the first enclosure removed is put into the accommodating appliance 31 at first, and then the lamp panel with the first enclosure removed is slowly lowered down and completely located in the accommodating appliance 31. In this way, when the lamp panel with the first enclosure removed is placed, it is possible to avoid a generation of bubbles on the contact surface between the colloid on the lamp panel and the defoaming glue in the accommodating appliance 31.

In the step S30, the upper surfaces of the lamp beads 1 are immersed into the glue. That is, the glue completely covers the plurality of lamp beads 1 on the front surface of the panel body. In this way, when the step S50 is performed, only the colloid formed on the lamp panel is in contact with the defoaming glue in the accommodating appliance 31, and the lamp beads 1 will not form direct contact with the defoaming glue in the accommodating appliance 31, such that the generation of bubbles is effectively avoided.

As shown in FIG. 1 to FIG. 3, between the step S10 and the step S30, the method for preparing the LED display module further includes: step S20: machining a second enclosure 20 around the back surface of the lamp panel. In this way, the second enclosure 20 blocks the back surface of the lamp panel, so as to prevent the glue or the defoaming glue from flowing to the back surface of the lamp panel.

Specifically, in the present embodiment, the first enclosure 10 and the second enclosure 20 are both adhesive tapes that are made of a PE, PU or an EVA material, and the first enclosure 10 and the second enclosure 20 are bonded to a periphery of the lamp panel.

As shown in FIG. 1 to FIG. 3, the step S30 includes: step S31: filling the accommodating pool with the glue, and performing the vacuum defoaming treatment in a vacuum box on the lamp panel filled with the glue, so as to extract bubbles in the lamp panel filled with the glue; and step S32: performing the vacuum defoaming treatment for 3 minutes to 10 minutes, so as to obtain the defoamed lamp panel. In this way, since the vacuum defoaming treatment is performed for 3 minutes to 10 minutes, the bubbles in the lamp panel filled with the glue are maximally extracted. The time for the vacuum defoaming treatment is preferably 3 minutes or 5 minutes or 8 minutes or 10 minutes.

As shown in FIG. 1 to FIG. 3, the step S40 includes: step S41: placing the defoamed lamp panel in a curing chamber to perform the first curing treatment, wherein a temperature in the curing chamber is between 20° C. and 40° C.; and step S42: performing the first curing treatment for 1 hour to 4 hours, so as to obtain the lamp panel that has been subjected to the first curing treatment. In this way, after the step S41 and the step S42, a viscosity of the glue on the lamp panel that has been subjected to the first curing treatment is greater and greater to form a sticky colloid, so that when the front surface of the lamp panel that has been subjected to the first curing treatment is placed downward, the glue on the lamp panel will not drop from the lamp panel. The temperature in the curing chamber is preferably 20° C. or 30° C. or 40° C., and a time for the first curing treatment is preferably 1 hour or 2 hours or 3 hours or 4 hours.

As shown in FIG. 1 to FIG. 3, to ensure that the glue on the lamp panel that has been subjected to the first curing treatment is firmly adhered to the front surface of the lamp panel without dropping, in the step S42: the viscosity of the glue on the lamp panel that has been subjected to the first curing treatment is between 2000 mPa·s and 10000 mPa·s. The viscosity of the glue on the lamp panel that has been subjected to the first curing treatment is preferably 2000 mPa·s or 4000 mPa·s or 6000 mPa·s or 8000 mPa·s or 10000 mPa·s.

As shown in FIG. 1 to FIG. 3, the step S50 includes: step S51: fabricating, by using a flexible film, the accommodating appliance 31 capable of accommodating the lamp panel that has been subjected to the first curing treatment; that is, a volume of the accommodating appliance 31 is greater than that of the lamp panel that has been subjected to the first curing treatment, so that the lamp panel that has been subjected to the first curing treatment completely falls into the accommodating appliance 31. At the same time, in order to ensure no bubble inside the accommodating appliance 31, step S52: filling the accommodating appliance 31 with the defoaming glue, so that the accommodating appliance 31 contains the defoaming glue; and step S53: removing the first enclosure 10, and placing the lamp panel with the first enclosure removed in the accommodating appliance 31, enabling the front surface of the lamp panel with the first enclosure removed to face the bottom of the accommodating appliance 31, and immersing the lamp beads 1 on the lamp panel with the first enclosure removed into the defoaming glue. In this way, in a process of placing the lamp panel with the first enclosure removed into the accommodating appliance 31, the colloid on the lamp panel with the first enclosure removed forms liquid-liquid contact with the defoaming glue, so that the colloid on the lamp panel with the first enclosure removed is completely fused with the defoaming glue, thereby removing the residual air in the front surface of the LED display module as much as possible, and the probability that the surfaces of the lamp beads 1 contact the colloid surface to generate bubbles is thus effectively reduced. A material of the flexible film is preferably Pet, PP, PVC, PE or PS. In this way, both surfaces of the flexible film are smooth or one surface is smooth and the other surface is frosted, so as to ensure that a release coating can be formed in advance on a surface of the flexible film that contacts the defoaming glue and the colloid on the lamp panel. Specifically, the release coating is arranged on a contact surface (i.e., an inner surface of the flexible film) of the flexible film with the defoaming glue and the colloid on the lamp panel, so as to facilitate a separation of the flexible film from a cured colloid after the LED display model is prepared.

In the present embodiment, since the inner surface of the flexible film is provided with the release coating, if the glue is first poured into the accommodating appliance 31 and then the vacuum defoaming treatment is performed, the release coating will be separated from the flexible film during the vacuum defoaming treatment, therefore, the accommodating appliance 31 is directly filled with defoaming glue that has been subjected to the vacuum defoaming treatment. When the glue is poured into the accommodating pool, even if the glue is subjected to a defoaming treatment in advance, bubbles are likely to be generated during a contact process of the glue and the surfaces of the lamp beads 1, therefore the glue is filled into the accommodating pool at first, and then the vacuum defoaming treatment is performed.

For LED display modules with different shapes in the related art, a plurality of molds need to be produced, which results in a higher cost. In the present embodiment, in the case of fabricating the accommodating appliance 31 by using the flexible film, the flexible film can be arbitrarily cut, so that it is easy to make a mold shape, and a cost is lower.

As shown in FIG. 1 to FIG. 3, in order to ensure that, after the front surface of the lamp panel with the first enclosure removed is placed facing the bottom of the accommodating appliance 31, the front surface of the lamp panel with the first enclosure removed is smoothly in contact with the bottom of the accommodating appliance 31, in the step S51, the accommodating appliance 31 is placed on a flat plate 32, so that the bottom of the accommodating appliance 31 forms the plane portion.

As shown in FIG. 1 to FIG. 3, the step S60 includes: step S61: placing a fixture 33 on the back surface of the lamp panel with the first enclosure removed; and step S62: placing a counterweight block 34 above the fixture 33, so that the fixture 33 applies an acting force, which faces the bottom of the accommodating appliance 31, to the back surface of the lamp panel with the first enclosure removed, and then the immersed lamp panel is obtained. The fixture 33 is placed on the back surface of the lamp panel with the first enclosure removed, and the counterweight block 34 uniformly applies the acting force, which faces the bottom of the accommodating appliance 31, to the fixture 33, therefore smoothness and uniformity of the colloid on the lamp panel that has been subjected to the second curing treatment are ensured. The fixture 33 includes a supporting plate and a plurality of supporting legs that are arranged on a lower surface of the supporting plate at intervals, the plurality of supporting legs avoid the plurality of electronic devices on the back surface of the lamp panel, that is, the plurality of supporting legs are supported at planar positions on the back surface of the lamp panel. On a premise of avoiding the electronic devices, the supporting legs are provided as many as possible, and the plurality of supporting legs are placed on the back surface of the lamp panel with the first enclosure removed, and when the counterweight block 34 uniformly applies the acting force, which faces the bottom of the accommodating appliance 31, to the fixture 33, a gravity of the counterweight block 34 is sufficiently dispersed, so as to ensure the smoothness and uniformity of the colloid on the lamp panel that has been subjected to the second curing treatment.

It should be noted that, a weight of the counterweight block 34 in the present embodiment can be selected according to requirements for applying counterweight to the lamp panel. Of course, in other feasible embodiments, the supporting legs are directly machined on the counterweight block, so that there is no need to set a fixture, but a production cost of directly machining the supporting legs on the counterweight block is higher.

As shown in FIG. 1 to FIG. 3, in the step S62, the counterweight block 34 is placed above the fixture 33, and to stably place the counterweight block 34 above the fixture 33 without dropping from the fixture 33, the counterweight block 34 is fixed on the fixture 33 with an adhesive tape, so that the fixture 33 applies the acting force, which faces the bottom of the accommodating appliance 31, to the back surface of the lamp panel with the first enclosure removed.

As shown in FIG. 1 to FIG. 3, the step S70 includes: step S71: placing the immersed lamp panel in the curing chamber to perform the second curing treatment, wherein the temperature in the curing chamber is between 20° C. and 1000° C.; step S72: performing the second curing treatment for 2 hours to 24 hours, so as to obtain the lamp panel that has been subjected to the second curing treatment, at this time, the colloid on the lamp panel that has been subjected to the second curing treatment has cured, thus having higher hardness; and step S73: removing the accommodating appliance 31, the flat plate 32 and an excess colloid around the lamp panel that has been subjected to the second curing treatment, so as to obtain the LED display module. The second enclosure and the adhesive tape are also removed. The manner of removing the excess colloid around the lamp panel can be cutting. The temperature in the curing chamber is preferably 20° C. or 30° C. or 40° C. or 50° C. or 60° C. or 70° C. or 80° C. or 90° C. or 100° C. The time for the second curing treatment is preferably 2 hours or 5 hours or 8 hours or 10 hours or 12 hours or 15 hours or 18 hours or 20 hours or 24 hours.

In the description of the present disclosure, it should be understood that orientation or position relationships indicated by orientation words such as “front, back, upper, lower, left, right”, “transverse, longitudinal, vertical, horizontal” and “top, bottom” and the like are generally orientation or position relationships shown on the basis of the drawings, and are merely for the convenience of describing the present disclosure and simplifying the description, in the absence of opposite statement, these orientation words do not indicate or imply that the referred devices or elements must have specific orientations or must be constructed and operated in specific orientations, and thus cannot be construed as limiting the protection scope of the present disclosure; and the orientation words “inside and outside” refer to the inside and outside of the contours of the components themselves.

For ease of description, spatially relative terms, such as “on”, “above”, “on the surface”, “over” and the like, may be used herein to describe spatial position relationships between one device or feature and other devices or features shown in the figures. It should be understood that, the spatially relative terms are intended to encompass different orientations of the device in use or operation in addition to the orientations depicted in the figures. For example, if the device in the figures is turned over, the device, which is described as “above other devices or features” or “over other devices or features” would then be oriented as “below other devices or features” or “beneath other devices or features”. Thus, the exemplary term “above” can encompass both orientations of “above” and “below”. The device may also be otherwise oriented (rotated by 90 degrees or at other orientations), and the spatially relative descriptions used herein are interpreted accordingly.

In addition, it should be noted that the terms “first”, “second” and the like are used for defining components and parts, and are merely for the convenience of distinguishing the corresponding components and parts, and unless otherwise stated, the above words have no special meaning, and thus cannot be construed as limiting the protection scope of the present disclosure.

The above descriptions are only preferred embodiments of the present disclosure, and are not intended to limit the present disclosure. For those skilled in the art, the present disclosure may have various modifications and changes. Any modifications, equivalent replacements, improvements and the like, made within the spirit and principle of the present disclosure, shall be included within the protection scope of the present disclosure.

1. A method for preparing an LED display module, comprising following steps:
step S10: machining a first enclosure around a front surface of a lamp panel, so as to form an accommodating pool on the front surface of the lamp panel;
step S30: filling the accommodating pool with glue, and performing a vacuum defoaming treatment on the lamp panel filled with the glue, so as to obtain a defoamed lamp panel;
step S40: performing a first curing treatment on the defoamed lamp panel, so as to obtain a lamp panel that has been subjected to the first curing treatment;
step S50: removing the first enclosure, and placing the lamp panel with the first enclosure removed in an accommodating appliance, enabling the front surface of the lamp panel with the first enclosure removed to face a bottom of the accommodating appliance, immersing lamp beads on the lamp panel with the first enclosure removed into defoaming glue in the accommodating appliance, wherein the bottom of the accommodating appliance is a plane portion;
step S60: applying an acting force, which faces the bottom of the accommodating appliance, to a back surface of the lamp panel with the first enclosure removed, and immersing the front surface of the lamp panel into the defoaming glue to obtain an immersed lamp panel; and
step S70: performing a second curing treatment on the immersed lamp panel, so as to obtain a lamp panel that has been subjected to the second curing treatment, and then the LED display module is obtained.

2. The method for preparing the LED display module as claimed in claim 1, wherein between the step S10 and the step S30, the method for preparing the LED display module further comprises:
step S20: machining a second enclosure around the back surface of the lamp panel.

3. The method for preparing the LED display module as claimed in claim 1, wherein the step S30 comprises:
step S31: filling the accommodating pool with the glue, and performing the vacuum defoaming treatment in a vacuum box on the lamp panel filled with the glue; and
step S32: performing the vacuum defoaming treatment for 3 minutes to 10 minutes, so as to obtain the defoamed lamp panel.

4. The method for preparing the LED display module as claimed in claim 1, wherein the step S40 comprises:
step S41: placing the defoamed lamp panel in a curing chamber to perform the first curing treatment, wherein a temperature in the curing chamber is between 20° C. and 40° C.; and
step S42: performing the first curing treatment for 1 hour to 4 hours, so as to obtain the lamp panel that has been subjected to the first curing treatment.

5. The method for preparing the LED display module as claimed in claim 4, wherein in the step S42: a viscosity of the glue on the lamp panel that has been subjected to the first curing treatment is between 2000 mPa • s and 10000 mPa • s.

6. The method for preparing the LED display module as claimed in claim 1, wherein the step S50 comprises:
step S51: fabricating, by using a flexible film, the accommodating appliance capable of accommodating the lamp panel that has been subjected to the first curing treatment;
step S52: filling the accommodating appliance with the defoaming glue, so that the accommodating appliance contains the defoaming glue; and
step S53: removing the first enclosure, and placing the lamp panel with the first enclosure removed in the accommodating appliance, enabling the front surface of the lamp panel with the first enclosure removed to face the bottom of the accommodating appliance, and immersing the lamp beads on the lamp panel with the first enclosure removed into the defoaming glue.

7. The method for preparing the LED display module as claimed in claim 6, wherein in the step S51, the accommodating appliance is placed on a flat plate, so that the bottom of the accommodating appliance forms the plane portion.

8. The method for preparing the LED display module as claimed in claim 1, wherein the step S60 comprises:
step S61: placing a fixture on the back surface of the lamp panel with the first enclosure removed; and
step S62: placing a counterweight block above the fixture, so that the fixture applies the acting force, which faces the bottom of the accommodating appliance, to the back surface of the lamp panel with the first enclosure removed, and then the immersed lamp panel is obtained.

9. The method for preparing the LED display module as claimed in claim 8, wherein in the step S62, the counterweight block is placed above the fixture, and the counterweight block is fixed on the fixture with an adhesive tape, so that the fixture applies the acting force, which faces the bottom of the accommodating appliance, to the back surface of the lamp panel with the first enclosure removed.

10. The method for preparing the LED display module as claimed in claim 7, wherein the step S70 comprises:
step S71: placing the immersed lamp panel in a curing chamber to perform the second curing treatment, wherein a temperature in the curing chamber is between 20° C. and 1000° C.;
step S72: performing the second curing treatment for 2 hours to 24 hours, so as to obtain the lamp panel that has been subjected to the second curing treatment; and
step S73: removing the accommodating appliance, the flat plate and an excess colloid around the lamp panel that has been subjected to the second curing treatment, so as to obtain the LED display module.

11. The method for preparing the LED display module as claimed in claim 1, wherein in the step S30, upper surfaces of the lamp beads are immersed into the glue.

12. The method for preparing the LED display module as claimed in claim 8, wherein a plurality of electronic devices are arranged on the back surface of the lamp panel, the fixture comprises a supporting plate and a plurality of supporting legs that are arranged on a lower surface of the supporting plate at intervals, and the plurality of supporting legs avoid the plurality of electronic devices.
